(19) United States
(12) Patent Application Publication
(10) Pub. No.: US 2006/0017094 A1
(43) Pub. Date: Jan. 26, 2006

(54) Non-volatile memory devices with improved insulation layers and methods of manufacturing such devices

(76) Inventors: Kwang-Bok Kim, Incheon-si (KR); Kyung-Hyun Kim, Seoul (KR); Young-Sun Ko, Gyeonggi-do (KR)

Correspondence Address: MYERS BIGEL SIBLEY & SAJOVEC, PO BOX 37428, RALEIGH, NC, 27627, US

(21) Appl. No.: 11/183,650

(22) Filed: Jul. 18, 2005

(30) Foreign Application Priority Data
Jul. 22, 2004 (KR) 2004-57295

(51) Int. Cl. H01L 29/788

(52) U.S. Cl. 257/315

(57) ABSTRACT

Non-volatile memory devices are provided which include a plurality of gate structures on a substrate. In these devices, a first insulation interlayer is on both the substrate and on the plurality of gate structures, and includes an opening therein. A common source line is in the opening in the first insulation interlayer. A top surface of the common source line is recessed below the top surface of the first insulation interlayer. A second insulation interlayer is on the first insulation interlayer and on the common source line.

### CROSS-REFERENCE TO RELATED APPLICATION

This application claims priority under 35 U.S.C. § 119 from Korean Patent Application No. 2004-57295, filed on Jul. 22, 2004, the disclosure of which is hereby incorporated by reference herein as if set forth in its entirety.

### FIELD OF THE INVENTION

The present invention relates to semiconductor devices and, more particularly, to non-volatile memory devices and methods of manufacturing such devices.

### BACKGROUND OF THE INVENTION

Random access memory (RAM) semiconductor devices, such as dynamic RAM (DRAM) and static RAM (SRAM) devices are volatile memory devices, meaning that the data stored in the device may be erased or lost when the power to the device is turned off. These volatile memory devices tend to operate at relatively high speeds. Non-volatile memory devices refer to memory devices which maintain stored data even after power to the device is turned off. However, non-volatile memory devices, such as read only memory (ROM) devices, tend to operate at relatively lower speeds.

Nonvolatile memory devices include mask ROM devices, erasable programmable ROM (EPROM) devices, electrically erasable programmable ROM (EEPROM) devices and flash erasable programmable ROM (FEPROM) devices. The data stored in mask ROM devices typically is programmed by the manufacturer and is neither erasable nor programmable, The data stored in EPROM, EEPROM and FEPROM devices typically can be erased and replaced with other data. Such memory devices are used in many applications such as in digital cellular phones, digital cameras, LAN switches and the like. In recent years, flash memory devices in particular have come into wide use. The data stored in flash memory devices may typically be erased and reprogrammed relatively rapidly using Fowler-Nordheim tunneling (F-N tunneling) or a hot electron injection techniques.

Flash memory devices may mainly be classified into NAND type devices and NOR type devices. The NOR type flash memory devices tend to provide higher operation speeds, while NAND type flash memory devices tend to provide a higher degree of integration.

FIGS. 1A and 1B are cross sectional diagrams that illustrate a method of manufacturing a conventional NAND type flash memory device.

Referring to FIG. 1A, a tunnel oxide layer (a gate oxide layer) may be formed on a semiconductor substrate 10. The semiconductor substrate 10 may be divided into a field region and an active region by a conventional isolation process such as, for example, a shallow trench isolation (STI) process. A first polysilicon layer is formed on the substrate 10, and a dielectric layer such as, for example, an oxide/nitride/oxide (ONO) multi-layer is formed on the first polysilicon layer. A second polysilicon layer which may be used to form a control gate 20 and a tungsten silicide layer may then be sequentially formed on the ONO multi-layer.

Next, an oxide layer may be coated on the tungsten silicide layer using, for example, a plasma-enhanced chemical vapor deposition (PECVD) process or a low pressure CVD (LPCVD) process, to form a hard mask layer on the tungsten silicide layer. An insulation material such as, for example, silicon oxynitride (SiON) may then be deposited on the hard mask layer to form an anti-reflection layer (ARL), which is not depicted in FIG. 1A. The hard mask layer may then be patterned into a hard mask pattern 22 using, for example, a photolithography process, and the tungsten silicide layer, the second polysilicon layer, the dielectric layer and the first polysilicon layer may be etched using the hard mask pattern as an etching mask to form, for example, a plurality of gates for memory cell transistors and one or more selection transistors of the flash memory device. As shown in FIG. 1A, the gate structure that is formed on the substrate 10 may comprise a gate oxide layer 12, a first polysilicon layer 14, an ONO dielectric layer 16, a second polysilicon layer 18, a tungsten silicide layer 19 and the hard mask pattern 22.

Next, a first insulation interlayer 24 may be formed on the substrate 10 and the above described gate structures. The first insulation interlayer may be used, for example, to electrically isolate the gate structures from a common source line (CSL) that is formed in a subsequent processing step. The first insulation interlayer 24 is typically planarized to a predetermined depth using a planarization process such as, for example, a chemical mechanical polishing (CMP) process.

As is also shown in FIG. 1A, a portion of the first insulation interlayer 24 may then be etched away to form a source line opening 26. Then, a metal layer (not shown) such as, for example, a tungsten layer is formed on the first insulation interlayer 24 to a sufficient thickness to fill up the source line opening 26. This metal layer is then removed and planarized using a CMP process to expose the first insulation interlayer 24, to form the CSL 28 in the source line opening 26. In the above-described CMP process, the first insulation interlayer 24 may act as a stop layer in the CMP process. In typical devices, the thickness of the portion of the first insulation interlayer 24 that extends above the top surfaces of the gate structures (distance “c” in FIG. 1A) may be about 1500 Å. This portion of the first insulation interlayer 24 may facilitate protecting the gate structures from damage during the CMP process.

As shown in FIG. 1B, a second insulation interlayer 30 such as, for example, a tetraethylorthosilicate (TEOS) layer may be formed on the substrate after formation of the CSL 28 in order to electrically isolate the CSL 28 from a bit line plug that is formed in a subsequent processing step. A portion of the second insulation interlayer 30 and the first insulation interlayer 28 may then be sequentially etched to form a contact plug opening 32.

A doped polysilicon layer may then be formed on the second insulation interlayer 30 to a sufficient thickness to fill up the contact plug opening 32. The doped polysilicon layer may then be removed and planarized using, for example, a CMP process to expose the second insulation interlayer 30. In this manner, the doped polysilicon bit line plug 34 may be formed between the active region of the substrate and a bit line of the flash memory device that is formed in a subsequent processing step. A metal layer 36 such as a tungsten layer is then formed on the bit line plug 34 and the second insulation interlayer 30, and then is patterned by a conventional photolithography process, to form a bit line that is electrically connected to the bit line plug 34.

The thickness of the buffer layer that is provided between the CSL and the bit line (distance “e” in FIG. 1B) may be set by adjusting the thickness of the second insulation interlayer 30. The buffer layer is usually formed to a thickness of about 4500 Å in order to electrically isolate the CSL from the bit line.

In conventional flash memory devices, the first insulation interlayer 24 is formed to a thickness of about 5000 Å (see distance “b” in FIG. 1B). As noted above, the CMP process that is used in forming the CSL 28 is typically stopped approximately 1500 Å above the top surface of the gate structures (see distance “c” in FIG. 1B). The thickness of the buffer layer between the CSL and the bit line (distance “e” in FIG. 1B) is typically about 4500 Å. Thus, the total thickness of the insulation interlayer (see distance “d” in FIG. 1B) is on the order of 9500 Å. A series of photolithography processes are typically performed on the insulation interlayer in order to form other layers such as, for example, metal layers thereon.

### SUMMARY OF THE INVENTION

Pursuant to embodiments of the present invention, non-volatile memory devices are provided which include a plurality of gate structures on a substrate. In these devices, a first insulation interlayer is on both the substrate and on the plurality of gate structures, and includes an opening therein. A common source line is in the opening in the first insulation interlayer. A top surface of the common source line is recessed below the top surface of the first insulation interlayer. A second insulation interlayer is on the first insulation interlayer and on the common source line.

In certain embodiments of these non-volatile memory devices, the portion of the second insulation interlayer on the first insulation interlayer may have a first thickness and the portion of the second insulation interlayer on the common source line may have a second thickness that is greater than the first thickness. The non-volatile memory device may also include a bit line contact plug that penetrates the second insulation interlayer and the first insulation interlayer to electrically connect to an active region of the device.

In these devices, the top surfaces of the plurality of gate structures may be further above the substrate than is the top surface of the common source line. Moreover, the first insulation interlayer may comprise a multi-layer structure that includes a first insulation layer on the substrate and on the plurality of gate structures and a second insulation layer that is a different material on the first insulation layer. In such embodiments, the first insulation layer may be a first height above the substrate in an operational region of the memory device and may be a second height above the substrate, that is less than the first height, in a non-operational region of the device. By way of example, the first height may be greater than about 2500 Angstroms and the second height may be less than about 1500 Angstroms in specific embodiments of the present invention. In certain embodiments, the top surface of the common source line may be recessed below the top surface of the first insulation interlayer by between about 500-3000 Angstroms. Likewise, the second insulation interlayer may, for example, have a thickness of about 4500 Å from the top surface of the common source line.

The first insulation layer may, for example, comprise a high-density plasma oxide and/or an undoped silicate glass, and the second insulation layer may, for example, comprise tetraethylorthosilicate (TEOS) and/or orthosilicate (OS). The second insulation interlayer may, for example, comprise a plasma-enhanced tetraethylorthosilicate (PE-TEOS) layer and/or a plasma-enhanced oxysilane (PE-OxSi) layer.

Pursuant to further embodiments of the present invention, methods of manufacturing a non-volatile memory device are provided in which a plurality of gate structures are formed on a semiconductor substrate. A first insulation interlayer is formed on the substrate and the gate structures. A common source line is formed that penetrates the first insulation interlayer to make electrical contact with the substrate in such a way that the top surface of the common source line is below the top surface of the first insulation interlayer. A second insulation interlayer is formed on the common source line and the first insulation interlayer. Finally, a bit line plug is formed that penetrates the second insulation interlayer to make electrical contact with the substrate.

In certain embodiments of these methods, the first insulation interlayer may be formed by forming a first insulation layer on the gate structures and on portions of the substrate between the gate structures, forming a second insulation layer on the first insulation layer, and then planarizing the second insulation layer. The first insulation layer may have a substantially uniform thickness. In certain embodiments, the top surface of the first insulation interlayer may be less than about 1000 Angstroms above the substrate on portions of the first insulation interlayer that are between the gate structures, and the top surface of the first insulation interlayer may be more than about 3000 Angstroms above the substrate on portions of the first insulation interlayer that are on the gate structures.

In other embodiments of these methods, the second insulation layer may be formed to a thickness of about 5000 Å. The first insulation layer may, for example, comprise a high-density plasma oxide and/or an undoped silicate glass, and the second insulation layer may, for example, comprise tetraethylorthosilicate (TEOS) and/or orthosilicate (OS).

In some embodiments of the present invention, the common source line may be formed by selectively removing a portion of the first insulation interlayer to form a first opening that partially exposes the substrate. Then, a first conductive layer is formed on the first insulation interlayer and in the first opening. Portions of the first conductive layer outside the first opening may then be removed, and an upper portion of the first conductive layer in the first opening may also be removed so that an upper surface of the first conductive layer is recessed from the top surface of the first insulation interlayer. The portions of the first conductive layer outside the first opening may be removed, for example, by performing a chemical mechanical polishing (CMP) process on the first conductive layer. The upper portion of the first conductive layer in the first opening may be removed, for example, using a dry etch-back. In certain embodiments of the present methods, the upper surface of the first conductive layer may be recessed between about 500 Å to 3000 Å from the top surface of the first insulation layer.

In these methods, the bit line plug may be formed, for example, by forming a second opening in the second insulation interlayer and the first insulation interlayer, and then forming a second conductive layer on the second insulation interlayer and in the second opening. Then, the portion of the second conductive layer that is on the upper surface of the second insulation interlayer may be removed to leave a bit line plug in the second opening.

### BRIEF DESCRIPTION OF THE DRAWINGS

The above and other features and advantages of embodiments of the present invention will become readily apparent by reference to the following detailed description considered in conjunction with the accompanying drawings, in which:

FIGS. 1A and 1B are cross sectional diagrams that illustrate methods of manufacturing a conventional NAND type flash memory device;

FIG. 2 is a schematic diagram illustrating a layout of a NAND type flash memory device according to some embodiments of the present invention;

FIG. 3 is a cross sectional diagram taken along line I-I′ of FIG. 2;

FIGS. 4A to 4H are cross sectional diagrams illustrating processing steps for methods of manufacturing non-volatile memory devices according to certain embodiments of the present invention; and

FIGS. 5A to 5C are cross sectional diagrams illustrating processing steps for forming second insulation interlayers and bit line contact plugs according to further embodiments of the present invention.

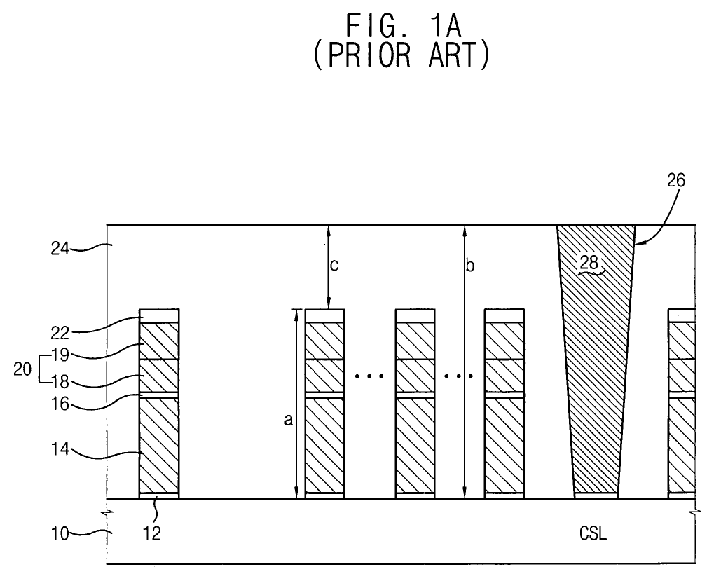

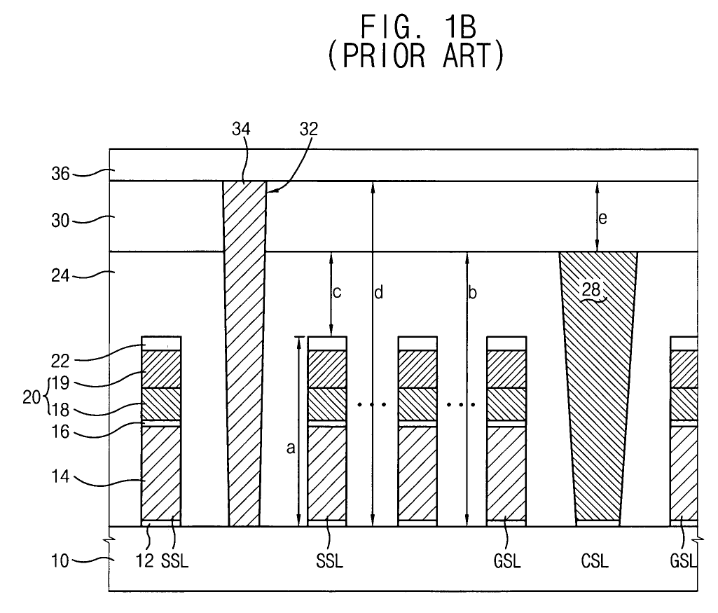

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, the term “and/or” includes any and all combinations of one or more of the associated listed items.

It also will be understood that, as used herein, the terms “row” and “column” indicate two non-parallel directions that may be orthogonal to one another. However, the terms row and column do not indicate a particular horizontal or vertical orientation.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could, for example, be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” comprising,” “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present invention now will be described more fully hereinafter with reference to the accompanying drawings in which exemplary embodiments of the present invention are shown.

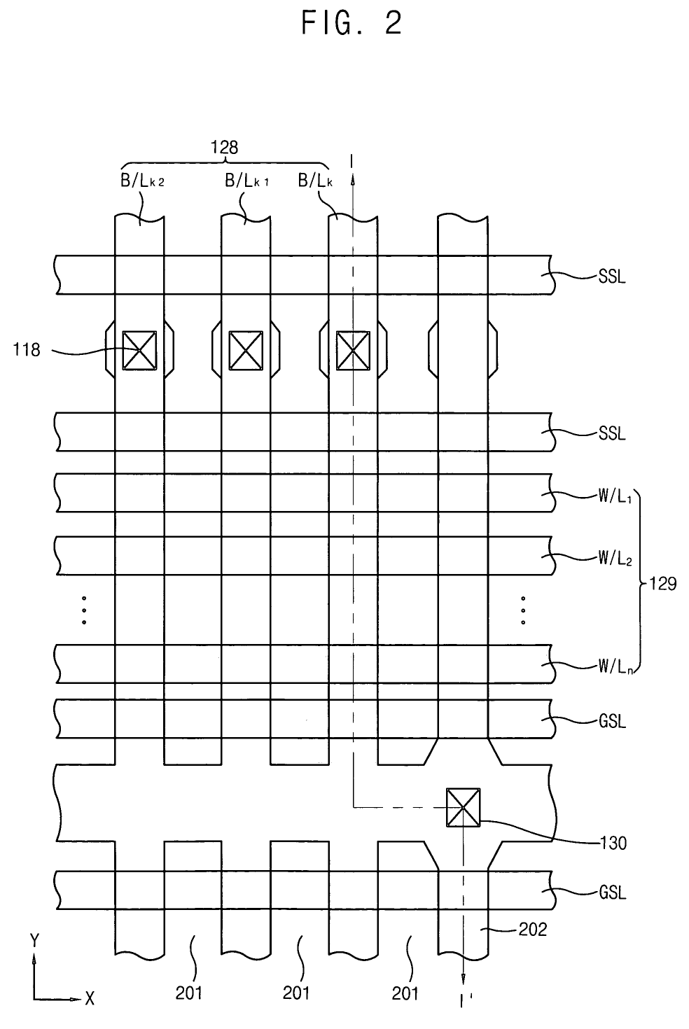

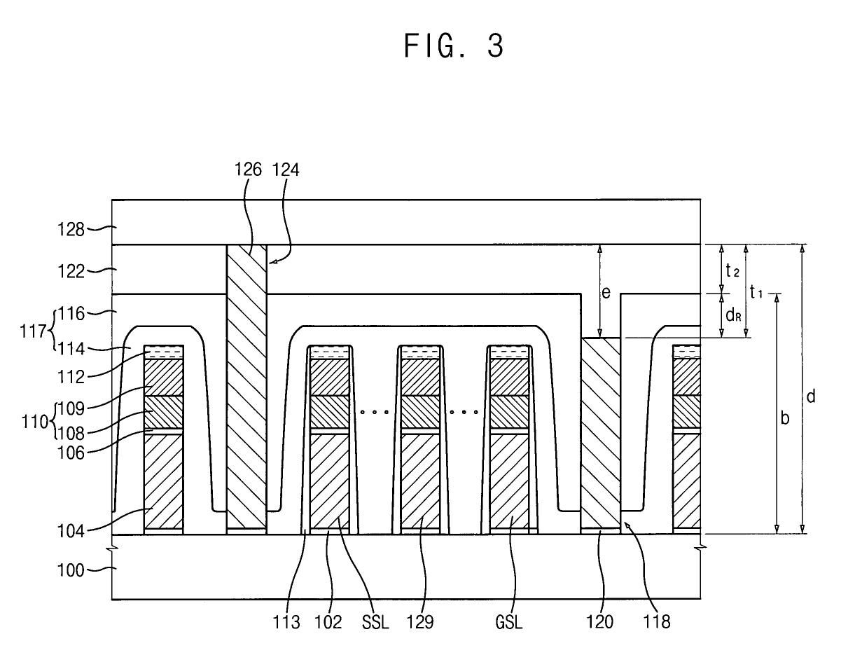

FIG. 2 is a schematic diagram illustrating the layout of a NAND type flash memory device according to an exemplary embodiment of the present invention, and FIG. 3 is a cross sectional diagram taken along the line I-I′ of FIG. 2.

As shown in FIGS. 2 and 3, a plurality of active regions 202 are arranged on a semiconductor substrate 100, such as, for example, a silicon wafer, in an X direction. Each of the active regions 202 is defined by a field region 201, and the active regions 202 extend in a Y direction. The channels and the source/drain regions of the memory cell transistors of the device are formed in the active regions 202. A plurality of word lines W/L₁ through W/Lₙ 129 are provided on the active region 202 in the Y direction. Each of the word lines 129 extends in the X direction. A memory cell transistor may be formed at or adjacent to each intersection of an active region 202 and a word line 129. Each of the memory cell transistors may be formed with a stacked gate structure that includes a floating gate 104 and a control gate 110, as described in detail herein. The source/drain regions of the memory cell transistors may be formed on a surface portion of the active regions 202 between the word lines 129.

A series of transistors may be arranged in the X direction spaced apart from the first word line W/L₁, and a second series of transistors may be arranged in the X direction spaced apart from the n^{th} word line W/Lₙ, (which may be the word line furthest from the first word line W/L₁). Hereinafter, the series of transistors spaced apart from the first word line W/L₁ is referred to as a string selection line SSL, and the series of transistors spaced apart from the last word line W/Lₙ is referred to as the ground selection line GSL. The transistors in the SSL may be used to select an active word line and the transistors in the GSL may be used to select a non-active word line among the word lines W/L₁ through W/Lₙ 129. Herein the transistors in the SSL and the GSL are referred to as selection transistors, whereas the transistors in the memory cell region are referred to as cell transistors.

The selection transistors in the SSL and GSL may include a contact hole (not shown) that is used to electrically connect the floating gate 104 and the control gate 110 of the selection transistor with each other in the field region between the input and output ports. This may facilitate reducing the signal delay. In such embodiments, the selection transistor may effectively operate like a single gate metal oxide semiconductor (MOS) transistor.

Typically, a flash memory device will include a plurality of operation units. Each operation unit may include a plurality of memory cell transistors and corresponding SSLs and GSLs. Neighboring operation units may be spaced apart by a separation distance from each other. The SSL of a first operation unit may, for example, be spaced apart by a separation distance from an SSL of a second, neighboring operation unit, and a GSL of a first operation unit may be spaced apart by a separation distance from another GSL of a neighboring operation unit. Hereinafter, the portion of the substrate 100 that corresponds to the operation units is referred to as the operational region (OR), and the portion of the substrate 100 corresponding to the space between the SSLs and the GSLs is referred to as the non-operational region (non-OR).

As shown in FIG. 3, in exemplary embodiments of the present invention, the gate structure of the cell transistors and the selection transistors may each include a gate oxide layer 102 on the substrate 100, a floating gate 104 on the gate oxide layer 102, a dielectric layer 106 on the floating gate 104, a control gate 110 on the dielectric layer 106, and a hard mask layer 112. In the embodiments of FIG. 3, a gate spacer 113 is further formed on one or more sidewalls of the gate structures. The GSL may comprise a polysilicon layer or a metal silicide layer formed on the gate oxide layer 102.

In certain of the embodiments of the present invention, a first polysilicon layer that is doped with impurities may be deposited onto the gate oxide layer 102 through, for example, a low-pressure chemical vapor deposition (LPCVD) process to form the floating gate 104 on the gate oxide layer 102. Silane gas may, for example, be utilized as the source gas in such a LPCVD process. The dielectric layer 106 may, for example, be a composite layer having an oxide/nitride/oxide structure (ONO), or a tantalum oxide (TA2O5) layer. A second polysilicon layer that is doped with impurities may be deposited onto the dielectric layer 106 to form the control gate 110. An insulation material such as, for example, a nitride may be deposited onto the control gate 110 to form the hard mask layer 112.

As shown in FIGS. 2 and 3, a bit line contact hole 124 may be formed between the adjacent string selection lines SSL so that the neighboring SSLs may share the same bit line contact hole 124, exactly like a mirror image. A plurality of bit lines B/Lₖ through B/Lₖ₋ₙ 128 may be formed on the word lines 129, with a first insulation interlayer 117 and a second insulation interlayer 122 interposed between the word line 129 and the bit line 128. The bit lines 128 are arranged in the X direction (i.e., perpendicular to the word lines 129), and extend in the Y direction. A common source line CSL 120 may be formed between adjacent ground selection lines, and extends in the X direction. A metal contact 118 is formed over the common source line CSL 120.

The first insulation interlayer 117 may be formed on the substrate 100 to a first thickness such that the gate structures on the substrate 100 are covered by the first insulation interlayer 117. The common source line CSL 120 penetrates the first insulation interlayer 117. As shown in FIG. 3, the top surface of the common source line CSL 120 may be recessed from the top surface of the first insulation interlayer 117 so that the top surface of the common source line CSL 120 is a distance of d_{R} below the top surface of the first insulation interlayer 117.

As shown in FIG. 3, in certain embodiments, the first insulation interlayer 117 includes a first insulation layer 114 that fills the space between the gate structures and a second insulation layer 116 that is on the first insulation layer 114. The second insulation layer 116 may have a planarized top surface. The first insulation layer 114 may, for example, comprise a high-density plasma oxide or an undoped silicate glass that have a good gap-filling characteristic, and may, for example, be formed to a thickness of about 4000 Å. The second insulation layer 116 may, for example, comprise a tetraethylorthosilicate (TEOS) layer or an oxysilane layer formed through a plasma-enhanced CVD (PECVD) process, and may have a thickness, for example, of about 1000 Å. The second insulation layer 116 may, for example, act as a passivation layer that protects the gate structures during the chemical mechanical polishing (CMP) process that may be used in forming the common source line CSL.

The common source line CSL may, for example, comprise tungsten W. The gate structure may, for example, be formed to a thickness of about 3500 Å. The recessed depth d_{R} may be in a range of about 500 Å to about 3000 Å under the above conditions. The common source line 120 may have a height that is the same as, or lower than, or higher than, the height of the gate structures.

The second insulation interlayer 122 may be formed on the first insulation interlayer 117 and the common source line CSL 120. A bit line contact plug 126 may penetrate the second insulation interlayer 122 and the first insulation interlayer 117. The second insulation interlayer 122 and the first insulation interlayer 117 may be partially removed using a conventional etching process(es) to form an opening 124 through which an active region of the substrate 100 is at least partially exposed. The opening 124 may be filled with a conductive material to form the bit line contact plug 126 in the opening 124. The second insulation interlayer 122 may comprise, for example, a tetraethylorthosilicate (TEOS) layer or an oxysilane layer formed, for example, through a plasma-enhanced CVD (PECVD) process. The bit line contact plug 126, may for example, comprise polysilicon or a metal. A bit line may be formed on the second insulation interlayer 122 to be in electrical contact with the bit line contact plug 126.

As shown in FIG. 3, the thickness of the portion of the second insulation interlayer 122 above the CSL 120 is a distance “t₁”. However, the thickness of the portions of the second insulation interlayer 122 that are on the first insulation interlayer 117 may be reduced by as much as the recessed depth d_{R}. Thus, the thickness t₂ of the portion of the second insulation interlayer 122 on the first insulation interlayer 117 may be reduced by as much as the recess depth d_{R}. Accordingly, while the total thickness d of the insulation interlayer of the non-volatile memory device depicted in FIG. 3 may be reduced by as much as the recess depth d_{R}, the thickness t₁ of the buffer layer between the CSL 120 and the bit line 128 may remain unchanged. In the embodiment depicted in FIG. 3, the distance “e” may, for example, be about 4500 Å.

As the thickness of the insulation interlayer is increased, it may become more difficult to reduce or minimize the formation of gaps in the bit line contact plug. When such gaps are formed, the electrical resistance of the bit line contact plug may be increased. Additionally, the alignment margin for the etching process in which the contact plug opening is formed may generally be reduced in proportion to the thickness of the insulation interlayer. If sufficient alignment margin is not provided, bridge defects may arise between the bit line contact plugs. Non-volatile memory devices according to embodiments of the present invention may thinner insulation interlayers that may provide improved performance.

According to the above-described embodiments of the present invention, the total thickness d of the insulation interlayer may be reduced without reducing the thickness “e” of the buffer layer. This may improve the aspect ratio of the bit line contact hole. As a result, improved alignment margin may be obtained in the etching process that is used to form the bit line contact hole, which may reduce the incidence of bridge defects between the bit line contact plugs.

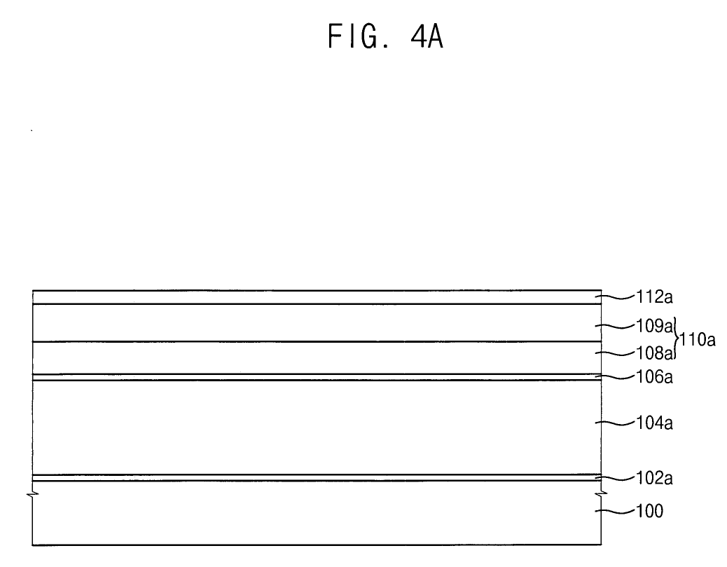

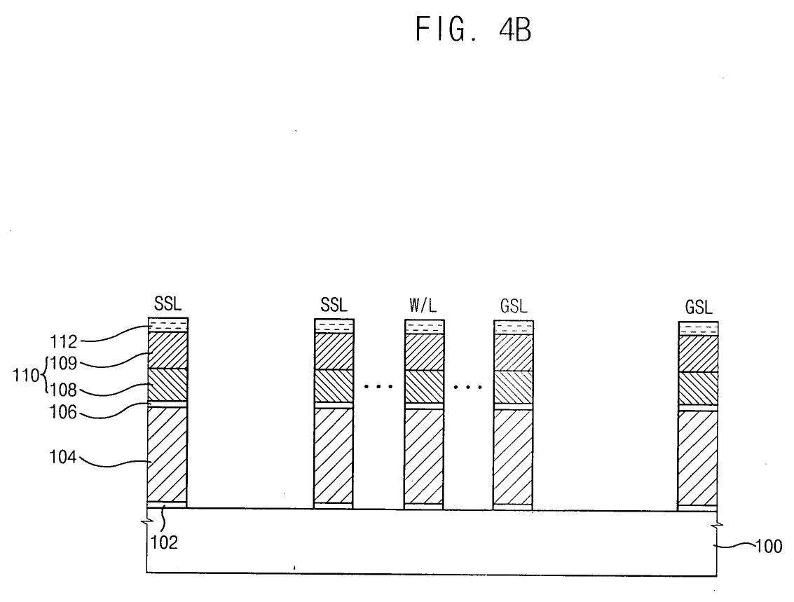

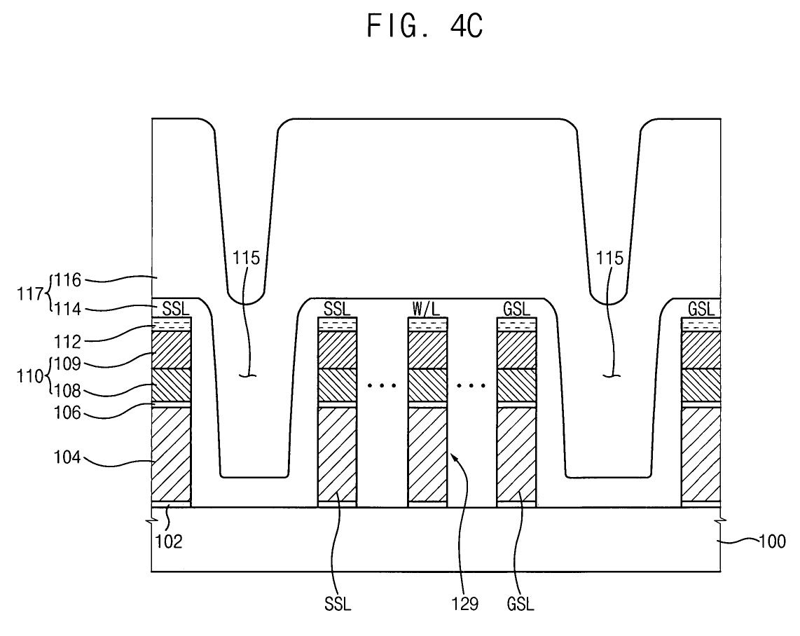

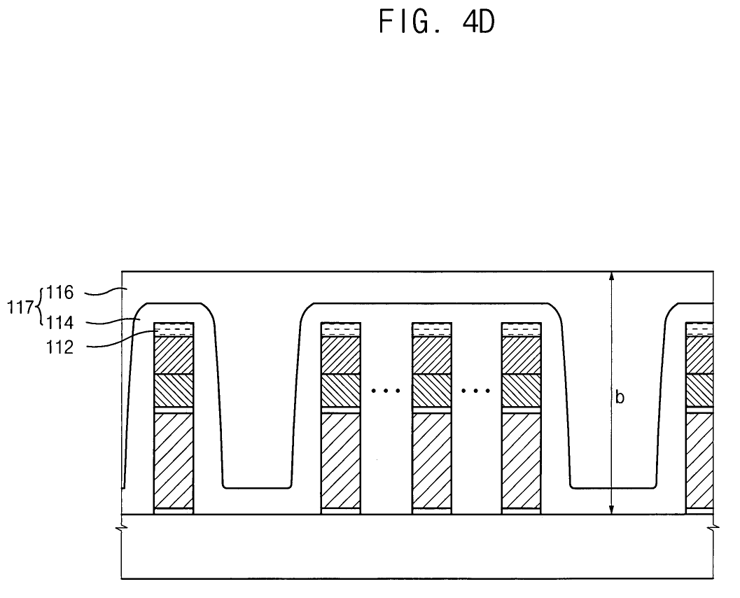

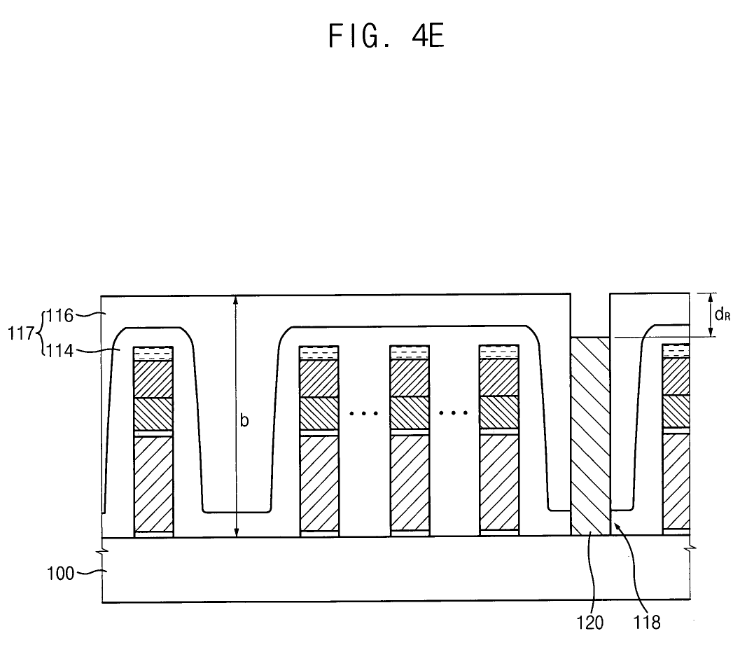

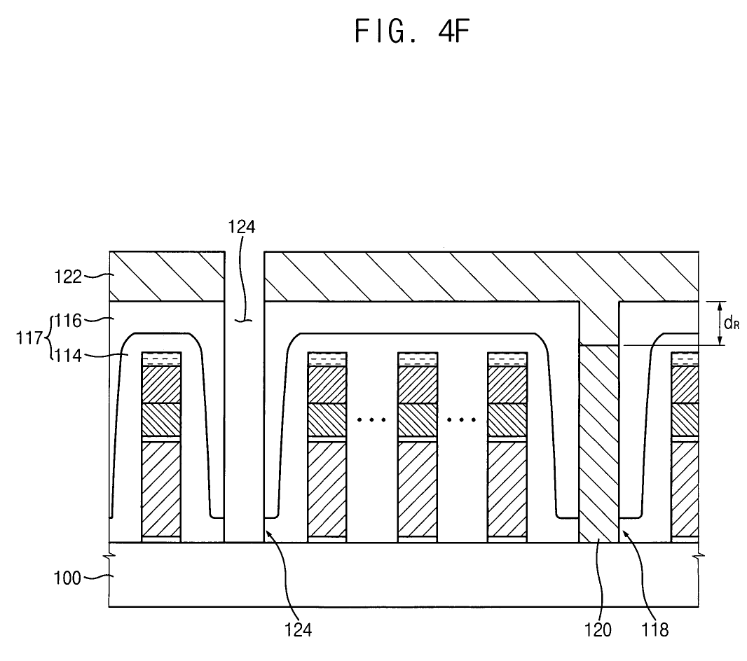

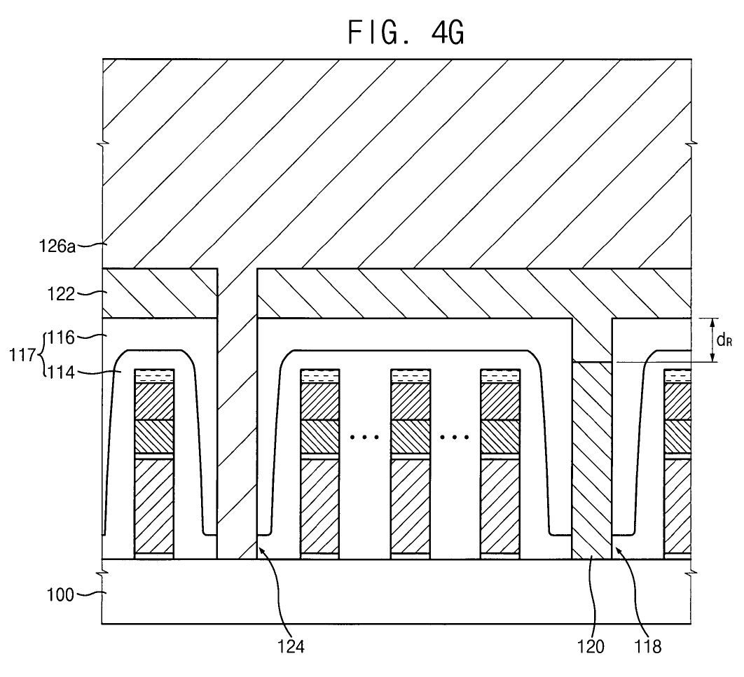

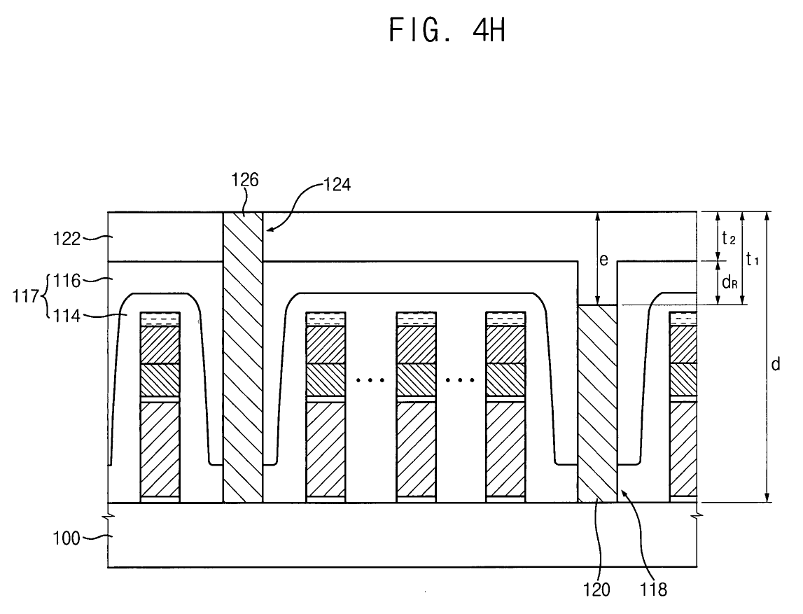

FIGS. 4A to 4H are cross sectional diagrams illustrating methods of manufacturing non-volatile memory devices according to exemplary embodiments of the present invention.

FIGS. 4A and 4B are cross sectional diagrams illustrating processing steps that may be used to form a plurality of gate structures on a substrate. Referring to FIG. 4A, an isolation process such as, for example, a shallow trench isolation (STI) process, is performed on a semiconductor substrate 100, and a field region 201 (see FIG. 2) is formed on the substrate 100. An active region 202 (see FIG. 2) is defined and enclosed by the field region 201 on the substrate 100. A thermal oxidation process may be performed on the active region 202 to form a tunnel oxide layer 102a in the active region 202. The tunnel oxide layer 102a may function as a gate oxide layer. In certain embodiments, a gate oxide layer may be formed first on the substrate 100, and portions of the gate oxide layer corresponding to the cell transistor may be removed through, for example, a wet etching process. Thereafter, the tunnel oxide layer may be formed in the same way as described above. The thickness of the gate oxide layer for the cell transistors may be different from the thickness of the gate oxide layer in the selection transistors.

Next, a lower conductive layer 104a may be formed on the substrate 100. The lower conductive layer 104a may comprise a doped polysilicon layer. As noted above, the lower conductive layer 104a is formed into the floating gates of the cell transistors in a subsequent process. A dielectric layer 106a such as, for example, an ONO layer is formed on the lower conductive layer 104a. An upper conductive layer 110a is formed on the dielectric layer 106a. The upper conductive layer 110a may, for example, comprise a multi-layer structure that includes a metal silicide layer 109a on a doped polysilicon layer 108a. The metal silicide layer may, for example, comprise a tungsten silicide layer. The upper conductive layer 110a is formed into a control gate of the cell transistor in a subsequent process. An insulation material such as an oxide or a nitride may then be deposited onto the upper conductive layer 110a to form a hard mask layer 112a.

Referring to FIG. 4B, the hard mask layer 112a is patterned through, for example, a conventional photolithography process to form a hard mask pattern 112 on the upper conductive layer 110a. Then, the upper conductive layer 110a, the dielectric layer 106a and the lower conductive layer 104a are selectively removed by, for example, a dry etching process that uses the hard mask pattern as an etching mask to form the gate structures of the cell transistors. Each gate structure may include a floating gate 104, a dielectric layer 106 and a control gate 110. As also indicated in FIG. 4B, the gate structures of the selection transistors of the SSL and GSL may be formed in the same manner at the same time that the gate structures of the cell transistors are formed.

FIGS. 4C and 4D are cross sectional diagrams illustrating processing steps for forming a first insulation interlayer according to certain embodiments of the present invention.

An ion implantation process may be performed on the substrate including the gate structures to form the source/drain regions (not shown) of the cell transistors and the selection transistors. Then, a first insulation layer 114 may be formed on the substrate 100, the gate structures and the source/drain regions, as shown in FIG. 4C.

The first insulation layer 114 may, for example, comprise a high-density plasma oxide or undoped silicate glass, and may be formed, for example, to a height of about 4000 Å above the surface of the substrate 100 in the operational region OR. While the OR may be relatively tightly packed with the gate structures for the cell transistors and the selection transistors, the non-operational region non-OR may be less highly integrated. Thus, the separation distance between the SSLs or the GSLs in the non-OR may be much greater than the gap between the gate structures in the OR, so that the gaps between the gate structures in the OR is sufficiently filled with the first insulation layer 114. Accordingly, the first insulation layer 114 covers the substrate 100 in the non-OR, and covers the gate structures in the OR, so that the first insulation layer 114 is uniformly formed across the substrate 100.

In the present embodiment, the first insulation layer 114 may be formed to a uniform thickness of about 500 Å since the gate structures have a height of about 3500 Å. As a result, the first insulation layer 114 may be formed uniformly on the substrate 100 along a profile of the gate structures in the operational region OR, and a gap 115 is formed between the SSLs and the GSLs in the non-OR. The first insulation layer 114 thus may have a height of about 4000 Å from the substrate 100 in the operational region OR, and may have a height of about 500 Å from the substrate 100 in the non-OR. While the first insulation layer exemplarily comprises the high-density plasma oxide or undoped silicate glass, those skilled in the art will recognize that a variety of materials could be utilized for the first insulation layer that have sufficient insulation and/or gap-filling characteristics.

Next, a second insulation layer 116 may be formed on the first insulation layer 114 to a sufficient thickness to fill up the gap 115. The second insulation layer 116 may be formed, for example, using a plasma-enhanced chemical vapor deposition (PECVD) process using tetraethylorthosilicate (TEOS) or oxysilane gas as a source gas. The second insulation layer 116 may protect the gate structures in the operational region OR from being eroded in a subsequent CMP process.

As shown in FIG. 4D, a portion of the second insulation layer 116 may then be removed and planarized, so that the thickness of the second insulation layer 116 is reduced, for example, to about 1000 Å from a top surface of the first insulation layer 114. Accordingly, in this exemplary embodiment, the first insulation interlayer 117 (which includes the first and second insulation layers 114 and 116) is formed to a thickness of about 5000 Å from the substrate 100 in both the OR and the non-OR. The second insulation layer 116 may be removed and planarized through, for example, a chemical mechanical polishing (CMP) process.

FIG. 4E is a cross sectional diagram illustrating processing steps for forming the common source line CSL according to some embodiments of the present invention. Referring to FIG. 4E, the first insulation interlayer 117 is partially etched through, for example, a photolithography process to expose a top surface of the substrate 100, thereby forming a first opening 118 through which the active region is partially exposed between the GSLs of adjacent operational units. Conductive materials may then be deposited onto the first insulation interlayer 117 to a sufficient thickness to fill up the first opening 118, thereby forming a first conductive layer (not shown) on the first insulation interlayer 117. The first conductive layer may then be removed and planarized to expose the first insulation interlayer 117, so that the first conductive layer remains only in the first opening 118. The first conductive layer remaining in the first opening 118 is then etched away to a recessed depth d_{R} using an etchant having an etching selectivity with respect to the first insulation interlayer 117, thereby forming the common source line CSL 120. As shown in FIG. 4E, the top surface of the CSL 120 is below the top surface of the first insulation interlayer 117 by as much as the recessed depth d_{R}. In the present embodiment, the first conductive layer may, for example, comprise a tungsten W layer, and the recessed depth d_{R} may be in the range of about 500 Å to about 3000 Å.

FIGS. 4F to 4H are cross sectional diagrams illustrating processing steps that may be used to form the second insulation interlayer according to certain embodiments of the present invention. Referring to FIG. 4F, insulation materials are deposited onto the first insulation interlayer 117 and the recessed CSL 120, thereby forming a second insulation interlayer 122. In the present embodiment, the second insulation interlayer 122 is exemplarily formed through a plasma-enhanced chemical vapor deposition (PECVD) process using tetraethylorthosilicate (TEOS) or oxysilane gas as a source gas.

The second insulation interlayer 122 and the first insulation interlayer 117 may then be partially etched using, for example, a photolithography process to form a second opening 124 that partially exposes the active region in the substrate 100 between the SSLs of adjacent operational units. Conductive materials may then be deposited onto the second insulation interlayer 122 to a sufficient thickness to fill up the second opening 124, thereby forming a second conductive layer 126a on the second insulation interlayer 122, as shown in FIG. 4G. In the present embodiment, the second conductive layer 126a may, for example, comprise a doped polysilicon layer. Then, the second conductive layer 126a and the second insulation interlayer 122 may be selectively removed such that the second conductive layer 126a remains only in the second opening 124, thereby forming the bit line contact plug 126 as shown in FIG. 4H. In the present embodiment, the second conductive layer 126a and the second insulation interlayer 122 may be removed through, for example, an etching process or a polishing process.

The thickness t₂ of the second insulation interlayer 122 in the operational region OR may be reduced as compared to conventional non-volatile memory devices, while the thickness t₁ of the second insulation interlayer 122 on the CSL 120 may remain unchanged. In certain embodiments of the present invention, the second insulation interlayer 122 may be removed such that the first thickness t₁ is about 4500 Å. A bit line is formed on the second insulation interlayer 122 in a subsequent process, so that the first thickness t₁ of the second insulation interlayer 122 corresponds to a thickness “e” of the buffer layer between the bit line and the CSL 120. The thickness “e” of the buffer layer may provide an operational margin in the flash memory device. Accordingly, the total thickness “d” of the insulation interlayer may be reduced by as much as the recess depth d_{R} without reducing the operational margin “e” between the bit line and the common source line 120.

For example, when the first insulation interlayer 117 has a thickness of about 5000 Å, and the gate structure has a thickness of about 3500 Å, the position of the CSL 120 may be varied in accordance with the recessed depth d_{R}. If the recess depth d_{R} is equal to about 1500 Å, the CSL 120 and the gate structure are about the same height above the substrate 100, so that the top surface of the CSL 120 is coplanar with the top surface of the gate structure. If the recessed depth d_{R} is greater than about 1500 Å, the top of CSL 120 is below the tops of the gate structures. If the recessed depth d_{R} is less than about 1500 Å, the top of the CSL 120 is above the tops of the gate structures and below the first insulation interlayer 117.

Although the above exemplary embodiments disclose that the bit line plug 126 and the second insulation interlayer 122 are simultaneously formed, the bit line plug 126 and the second insulation interlayer 122 may alternatively be formed in respective processes, as would be well known to one of the ordinary skill in the art.

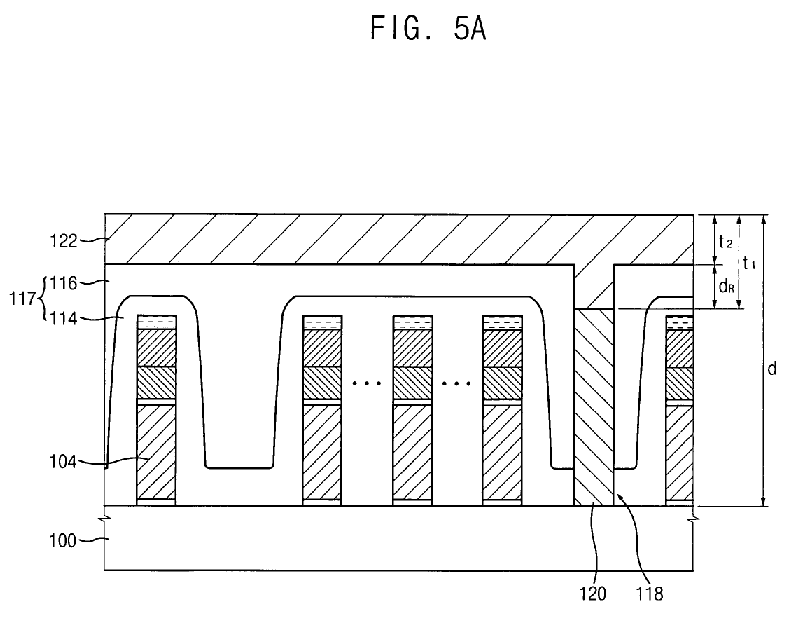

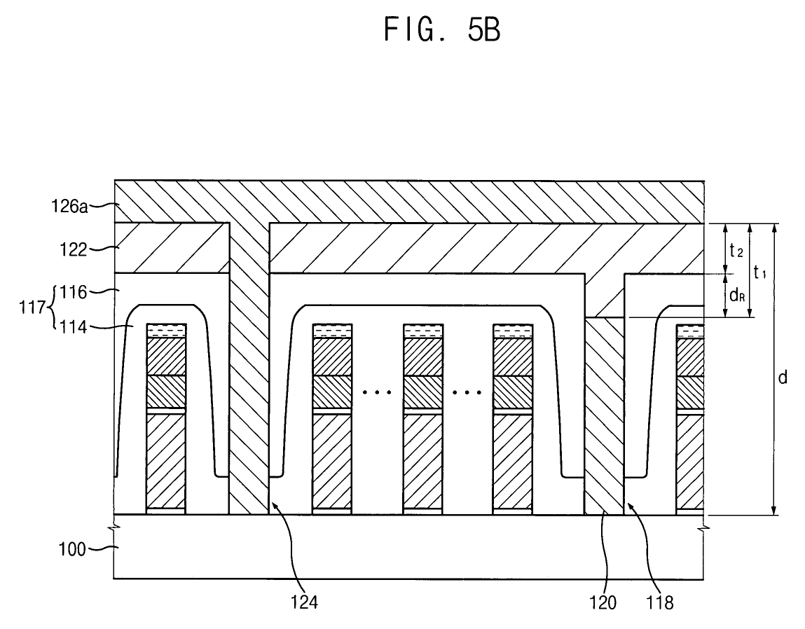

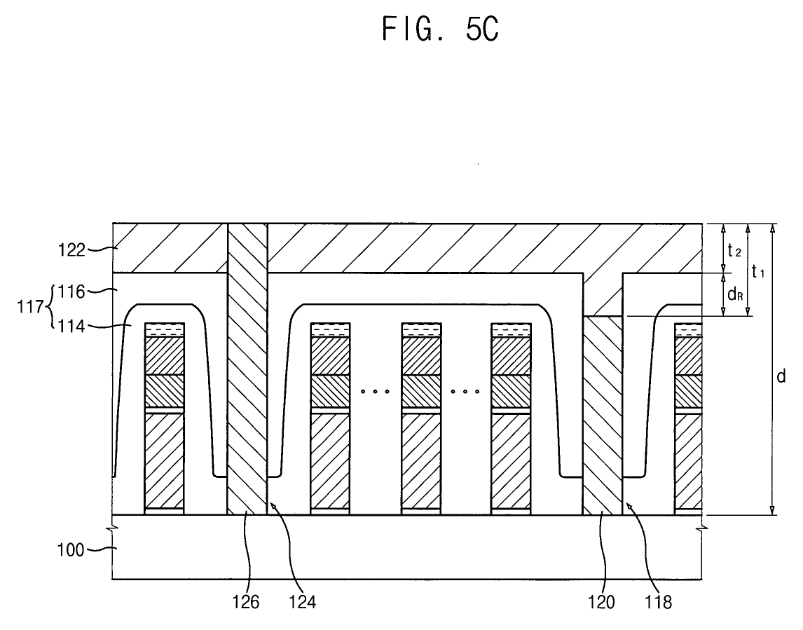

FIGS. 5A to 5C are cross sectional diagrams of processing steps for forming the second insulation interlayer and the bit line contact plug according to further embodiments of the present invention.

As shown in FIG. 5A, insulation materials are deposited onto the first insulation interlayer 117 and the CSL 120 to form a second insulation interlayer 122. In the present embodiment, the second insulation interlayer 122 may comprise, for example, a tetraethylorthosilicate (TEOS) layer, and is exemplarily formed to a thickness of about 4500 Å from a top surface of the common source line 120.

As shown in FIG. 5B, the second insulation interlayer 122 and the first insulation interlayer 117 are partially etched using, for example, a photolithography process to expose a top surface of the substrate 100. As a result, a second opening 124 is formed through which the active region is partially exposed between the SSLs of adjacent operational units. Conductive materials may then be deposited onto the second insulation interlayer 122 to a sufficient thickness to fill up the second opening 124, thereby forming a second conductive layer 126a on the second insulation interlayer 122. In the present embodiment, the second conductive layer 126a exemplarily comprises a polysilicon or a metal. Then, the second conductive layer 126a is selectively removed through, for example, an etching process or a polishing process to expose the second insulation interlayer 122, so that the second conductive layer 126a remains only in the second opening 124, thereby forming a bit line contact plug 126 as shown in FIG. 5C. The top surface of the bit line contact plug 126 is coplanar with the top surface of the second insulation interlayer 122.

Then, an etching stop layer (not shown) is formed on the bit line plug 126 and the second insulation interlayer 122. The etch stop layer may, for example, comprise a silicon oxynitride (SiON) layer formed through a plasma-enhanced chemical vapor deposition (PECVD) process. A plasma-enhanced TEOS layer may then be formed on the etch stop layer, and the plasma-enhanced TEOS layer and the etch stop layer may be selectively removed through one or more photolithography processes, so that a plurality of bit line insulation layers (not shown) are arranged on the second insulation interlayer 122 in the X direction. These bit line insulation layers may be spaced apart by a predetermined distance. The bit line insulation layers electrically insulate neighboring bit lines from each other, so that a bit line wiring is formed between neighboring bit line insulation layers.

According to some embodiments of the present invention, the thickness of the insulation interlayer may be reduced without reducing the operational margin between the bit line and the common source line. The height difference between the gate structure and an upper structure on the gate structure may be reduced, thereby reducing an electrical contact resistance of the upper structure. In addition, a sufficient alignment margins in subsequent processes such as photolithography processes may be maintained or improved even though the thickness of the insulation interlayer is reduced.

Although the exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A non-volatile memory device comprising:
a plurality of gate structures on a substrate;
a first insulation interlayer on the substrate and on the plurality of gate structures, the first insulation interlayer having an opening;
a common source line in the opening in the first insulation interlayer, wherein a top surface of the common source line is recessed below a top surface of the first insulation interlayer; and
a second insulation interlayer on the first insulation interlayer and on the common source line.

2. The non-volatile memory device of claim 1, wherein a portion of the second insulation interlayer on the first insulation interlayer has a first thickness and a portion of the second insulation interlayer on the common source line has a second thickness that is greater than the first thickness.

3. The non-volatile memory device of claim 2, further comprising a bit line contact plug that penetrates the second insulation interlayer and the first insulation interlayer to electrically connect to an active region of the non-volatile memory device.

4. The non-volatile memory device of claim 1, wherein the top surfaces of the plurality of gate structures are further above the substrate than is the top surface of the common source line.

5. The non-volatile memory device of claim 1, wherein the first insulation interlayer comprises:
a first insulation layer that comprises a first material on the substrate and the plurality of gate structures; and
a second insulation layer that comprises a second material which is different than the first material on the first insulation layer.

6. The non-volatile memory device of claim 5, wherein the first insulation layer is a first height above the substrate in an operational region of the memory device and is a second height above the substrate that is less than the first height in a non-operational region of the memory device.

7. The non-volatile memory device of claim 6, wherein the first height is greater than about 2500 Angstroms and wherein the second height is less than about 1500 Angstroms.

8. The non-volatile memory device of claim 1, wherein the first insulation layer comprises a high-density plasma oxide and/or an undoped silicate glass, and wherein the second insulation layer comprises tetraethylorthosilicate (TEOS) and/or orthosilicate (OS).

9. The non-volatile memory device of claim 1, wherein the second insulation interlayer comprises a plasma-enhanced tetraethylorthosilicate (PE-TEOS) layer and/or a plasma-enhanced oxysilane (PE-OxSi) layer.

10. The non-volatile memory device of claim 1, wherein the top surface of the common source line is recessed below the top surface of the first insulation interlayer by between about 500 to 3000 Angstroms.

11. The non-volatile memory device of claim 1, wherein the second insulation interlayer has a thickness of about 4500 Å from the top surface of the common source line.

12. A non-volatile memory device comprising:
a semiconductor substrate having an active region;
a plurality of gate structures on the active region;
a first insulation interlayer that comprises:
a first insulation layer of substantially uniform thickness on the gate structures and on the substrate; and
a second insulation layer that has a non-uniform thickness on the first insulation layer;
a common source line penetrating the first insulation interlayer to make electrical contact with the substrate, wherein a top surface of the common source line is positioned below a top surface of the first insulation interlayer;
a second insulation interlayer on the common source line and the first insulation interlayer; and
a bit line plug penetrating the second insulation interlayer and the first insulation interlayer to make electrical contact with the substrate.

13. The non-volatile memory device of claim 12, wherein the first insulation layer comprises a high-density plasma oxide and/or an undoped silicate glass, and wherein the second insulation layer comprises tetraethylorthosilicate (TEOS) and/or orthosilicate (OS).

14. The non-volatile memory device of claim 13, wherein the first insulation layer has a uniform thickness of about 500 Å, and wherein the top surface of the second insulation layer is about 4500-5500 Å above the substrate.

15. The non-volatile memory device of claim 12, wherein the second insulation interlayer comprises a plasma-enhanced tetraethylorthosilicate (PE-TEOS) layer and/or a plasma-enhanced oxysilane (PE-OxSi) layer.

16. The non-volatile memory device of claim 12, further comprising a bit line on the second insulation interlayer that is in electrical contact with the bit line plug.

17. The non-volatile memory device of claim 16, wherein the bit line plug comprises a polysilicon and/or a metal bit line plug, and wherein the bit line comprises tungsten.

18. The non-volatile memory device of claim 12, wherein the top surface of the common source line is between about 500 Angstroms and about 3000 Angstroms below the top surface of the first insulation interlayer.

19. The non-volatile memory device of claim 18, wherein a portion of the second insulation interlayer that is on the common source line has a thickness of about 4500 Å.

20. The non-volatile memory device of claim 12, wherein each of the gate structures comprises:
a gate oxide layer on the substrate;
a conductive floating gate on the gate oxide layer;
a dielectric layer on the floating gate;
a conductive control gate on the dielectric layer; and
a hard mask layer on the conductive control gate.

21. A method of manufacturing a non-volatile memory device, the method comprising:
forming a plurality of gate structures on a semiconductor substrate;
forming a first insulation interlayer on the substrate and the gate structures;
forming a common source line that penetrates the first insulation interlayer to make electrical contact with the substrate, wherein a top surface of the common source line is below a top surface of the first insulation interlayer;
forming a second insulation interlayer on the common source line and the first insulation interlayer; and
forming a bit line plug that penetrates the second insulation interlayer to make electrical contact with the substrate.

22. The method of claim 21, wherein forming the first insulation interlayer comprises:
forming a first insulation layer on the gate structures and on portions of the substrate between the gate structures;
forming a second insulation layer on the first insulation layer; and
planarizing the second insulation layer.

23. The method of claim 22, wherein the first insulation layer has a substantially uniform thickness, and wherein the top surface of the first insulation interlayer is less than about 1000 Angstroms above the substrate on portions of the first insulation interlayer that are between the gate structures, and wherein the top surface of the first insulation interlayer is more than about 3000 Angstroms above the substrate on portions of the first insulation interlayer that are on the gate structures.

24. The method of claim 23, wherein the second insulation layer is formed to a thickness of about 5000 Å.

25. The method of claim 22, wherein the first insulation layer comprises a high-density plasma oxide and/or an undoped silicate glass.

26. The method of claim 22, wherein the second insulation layer comprises tetraethylorthosilicate (TEOS) and/or orthosilicate (OS).

27. The method of claim 21, wherein forming the common source line comprises:
selectively removing a portion of the first insulation interlayer to form a first opening that partially exposes the substrate;
forming a first conductive layer on the first insulation interlayer and in the first opening;
removing portions of the first conductive layer outside the first opening; and
removing an upper portion of the first conductive layer in the first opening so that an upper surface of the first conductive layer is recessed from the top surface of the first insulation interlayer.

28. The method of claim 27, wherein the first conductive layer comprises tungsten.

29. The method of claim 27, wherein removing portions of the first conductive layer outside the first opening comprises performing a chemical mechanical polishing (CMP) process on the first conductive layer.

30. The method of claim 27, wherein the upper portion of the first conductive layer in the first opening is removed using a dry etch-back.

31. The method of claim 27, wherein the upper surface of the first conductive layer is recessed between about 500 Å to 3000 Å from the top surface of the first insulation layer.

32. The method of claim 21, wherein forming the bit line plug comprises:
partially removing the second insulation interlayer and the first insulation interlayer to form a second opening in the second insulation interlayer and the first insulation interlayer;
forming a second conductive layer on the upper surface of the second insulation interlayer and in the second opening; and
removing the portion of the second conductive layer that is on the upper surface of the second insulation interlayer.

33. The method of claim 32, wherein the second insulation interlayer comprises a plasma-enhanced oxide layer formed through a plasma-enhanced chemical vapor deposition (PECVD) process using tetraethylorthosilicate (TEOS) and/or oxysilane gas as a source gas.

34. The method of claim 33, wherein the second conductive layer comprises a polysilicon layer or a metal layer.

35. The method of claim 32, wherein the second conductive layer is removed using a chemical mechanical polishing (CMP) process.

36. The method of claim 32, wherein the first insulation interlayer is formed to a thickness of about 5000 Å measured from the substrate, and the second insulation interlayer is formed to a thickness of about 4500 Å measured from the top surface of the common source line.

37. The method of claim 32, wherein the second insulation interlayer and the first insulation interlayer are partially removed using a photolithography process.
